(19) United States
(12) Patent Application Publication
(10) Pub. No.: US 2025/0059665 A1
(43) Pub. Date: Feb. 20, 2025

(54) ELECTROLYTIC SOLUTION FOR COPPER FOIL, AND ELECTROLYTIC COPPER FOIL

(71) Applicant: Shenzhen Institute of Advanced Electronic Materials, Guangdong (CN)

(72) Inventors: Zhe Li, Guangdong (CN); Zhiquan Liu, Guangdong (CN); Liyin Gao, Guangdong (CN); Rong Sun, Guangdong (CN)

(73) Assignee: Shenzhen Institute of Advanced Electronic Materials, Guangdong (CN)

(21) Appl. No.: 18/722,176

(22) PCT Filed: Dec. 20, 2022
(86) PCT No.: PCT/CN2022/140405

§ 371 Date: Jun. 20, 2024

(30) Foreign Application Priority Data
Dec. 21, 2021 (CN) 202111574431.5

(51) Int. Cl. C25D 1/04; H01M 4/66; H05K 1/09; H05K 9/00

(52) U.S. Cl. CPC C25D 1/04; H05K 1/09; H05K 9/0084; H01M 4/661; H05K 2201/0355

(57) ABSTRACT

An electrolytic solution for a copper foil, and the preparation and use of an electrolytic copper foil. The electrolytic solution for a copper foil comprises an additive, wherein the additive comprises an inhibitor and an auxiliary agent. The auxiliary agent comprises at least one of polystyrene sulfonate, polyethylene sulfonate, alkyl sulfonate and alkylbenzene sulfonate, wherein both the alkyl sulfonate and the alkyl benzene sulfonate have ≥12 carbon atoms. By means of simple and convenient chemical regulation and control means such as the selection and combination of additives for an electrolytic (electroplating) solution, a pre-electroplated copper material resulting from electroplating using the electrolytic solution can form a high-proportion annealing twin boundary after a heat treatment at a temperature of ≥200° C., and has the unique mechanical characteristic of “annealing-induced strengthening and toughening”.

### CROSS REFERENCE TO RELATED APPLICATIONS

This application is a U.S. National Phase application filed under 35 U.S.C. § 371, based on International Patent Application No. PCT/CN2022/140405, filed Dec. 20, 2022, which claims priority to Chinese Patent Application No. 202111574431.5, filed on Dec. 21, 2021, which are incorporated herein by reference.

### TECHNICAL FIELD

The present application belongs to the technical field of advanced preparation, processing and molding of metallic and non-metallic materials, and specifically relates to an electrolytic solution for a copper foil, preparation for an electrolytic copper foil and use thereof.

### BACKGROUND

Electrolytic copper foil is one of the key raw materials for the manufacture of electronic circuits and lithium batteries, which plays an important role in signal and electricity transport. The formation mechanism of electrolytic copper foil is same as electroplating copper: firstly, a high purity copper material (such as copper wire) is put into a copper dissolving tank, and mixed with pure water and sulfuric acid, and compressed air is introduced to oxidize the copper, generating an electrolytic solution of copper sulfate; then, an organic additive is fed, direct current is applied between a titanium roller cathode and an insoluble anode, and thereby copper ions are reduced and crystallized on the surface of cathode, and eventually form the foil with the directional rotation and winding of the titanium roller. The properties of electrolytic copper foil are mainly related to the electrolytic solution composition, temperature, flow rate, cathode roller speed, current density and other parameters, wherein common organic additives include organic sulfides, amines, polyethers, organic dyes and their derivatives, etc., which can be used in combination to obtain a bright and flat coating with excellent mechanical properties, and it is an important means of regulating the surface state and crystallization behavior of the electrolytic copper foil.

Conventional electrolytic (electroplating) copper foil is composed of micron-sized columnar grains or equiaxed grains, which have higher tensile strength and lower ductility in the mechanical properties than bulk copper. Commercially available electrolytic copper foils with microcrystal organization exhibit “annealing-induced softening and toughening”, i.e., at common thermal treatment temperatures (e.g., 200-400° C.), recrystallization of the foil occurs as the annealing temperature increases and the period lengthens; such process comprises impurity diffusion, boundary migration, grain growth, defect reduction, stress release, etc. The final copper foil has reduced tensile strength and improved ductility at room temperature than before the annealing, and for example, the tensile strength is reduced by about half and the elongation is approximately doubled. For example, taking the conventional copper foil with a thickness of 70 μm for a copper-clad laminate as an example, its tensile strength is usually ≥250 MPa at room temperature, and its elongation is ≥5%; after thermal treatment at 180° C., the tensile strength is ≥150 MPa and the elongation is ≥10%.

The important development direction of high-performance electronic circuit copper foil is to improve the mechanical properties. For the electrolytic copper foil having nanotwinned copper organization, a high proportion of twin layers, which is perpendicular to the growth direction and densely grow along the (111) plane, contributes the improved thermal stability of material organization. Twin boundaries are one special kind of subgrain boundaries, and the growth of a high proportion of twin boundaries inside the grains is able to impede dislocation motion without causing significant electron scattering, resulting in ultra-high strength, non-degraded ductility and electrical conductivity of the copper. Literature reports that the tensile strength of copper foils is generally in the range of 400-1000 MPa, and the elongation is in the range of 3%-13%. Due to the lower energy of twin boundaries compared to normal grain boundaries, the migration of grain boundaries and grain growth are suppressed during the annealing or self-annealing process, and hence, the organization structure exhibits thermal stability, and the strength and elongation have no significant change over a certain temperature window. The copper foil having nanotwinned organization usually exhibits “non-softening and non-toughening after the annealing” or mild “annealing-induced softening and toughening”, and it is inhibited from recrystallization due to the stable growth of twins with high density; its tensile strength before annealing is 2-4 times the commercially available copper foil; although the strength decreases slowly as the annealing temperature increases, the elongation of copper foil is not significantly changed and sometimes even decreases to about half or less of the commercially available copper foil. According to Chin Chen's team at National Chiao Tung University, Taiwan (Materials 2020, 13, 1310), the electroplating twinned copper foil having the typical mid twinned layer spacing and mid grain size is annealed at 200-400° C. for 1 hour; with the annealing temperature increasing, on one hand, the grains with twinned organization grow, and the proportion of twin boundaries decreases; on the other hand, the tensile strength of the copper foil decreases from 500 MPa to 300 MPa, and the elongation at break increases from 5% to 20%. When the material is annealed at 400° C. for 3 hours, the twin boundaries almost disappear, and the tensile strength and elongation at break drop to 200 MPa and 10%, respectively. In addition, Chin Chen's team also reported an electrolytic foil with micro-twinned copper organization (Materials 2020, 13, 1211) which possesses a (110) preferred orientation, has thinner twin layers and is parallel to the growth direction. By annealing such material at 250° C. for 10 min, the tensile strength decreases from 500 MP to 400 MPa, and the elongation at break increases from 6% to 14%; obvious recrystallization is observed in the organization, the grains grow significantly, and the twin layers disappear. Although the high-temperature mechanical properties of the above two kinds of electrolytic copper foil materials with twinned organization have different degrees of enhancement, they both exhibit the behavior of “annealing-induced softening and toughening”.

In conclusion, the existing copper foils are unable to realize the improvement of tensile strength and elongation at the same time after being annealed, and it is of great significance to conduct further research.

### SUMMARY

In view of the above problems in the prior art, an object of the present application is to provide an electrolytic solution for a copper foil, preparation for an electrolytic copper foil and use thereof.

In order to achieve the above object, the present application adopts the technical solutions below.

An object of the present application is to provide an electrolytic solution for a copper foil. The electrolytic solution comprises an additive, the additive comprises an inhibitor and an auxiliary agent, and the auxiliary agent comprises at least one of polystyrene sulfonate, polyethylene sulfonate, alkyl sulfonate and alkylbenzene sulfonate;

wherein the alkyl sulfonate and the alkylbenzene sulfonate both have more than or equal to 12 carbon atoms, such as 12, 13, 14, 15, 16, 17, 18, 19, 20, 21, 22, 23 or 24.

The present application provides the electrolytic solution for a copper foil comprising particular additives. Through simple chemical regulation such as selection and combination of additives for the electrolytic (electroplating) solution, the pre-electroplated copper material, obtained by electroplating with the electrolytic solution, is capable of forming a high proportion of annealing twin boundaries after thermal treatment at 200° C. or higher temperature, possessing unique “annealing-induced strengthening and toughening” mechanical properties. The proportion of annealing twins increases with the increase of temperature, which greatly inhibits the recrystallization rate. The copper foil exhibits excellent mechanical properties. There is no significant grain growth under the experimental conditions of thermal treatment. The copper foil even has higher tensile strength than before the annealing, and at the same time its elongation increases by about a half. The copper foil of the present application has obvious advantages in mechanical properties, contrasting sharply with the general commercially available electrolytic (electroplated) copper foils and growth twinned copper foils which show high temperature mechanical behavior of “annealing-induced softening and toughening”.

Optionally, the inhibitor comprises gelatin, which enhances polarization and inhibits copper ion deposition by forming an adsorbent layer on the copper surface on the aspect of electrochemistry, and, on the aspect of organization regulation, provides a strong initial tensile stress and drives the nucleation of twin boundaries. Other inhibitor type (e.g., thiourea) that enhances polarization and inhibits deposition by forming a complex layer is not suitable because of the significant differences between those two in the electrochemical mechanism and micro-organization and material properties of the prepared copper foils.

Optionally, the gelatin has a coagulation value of 10-300 bloom. For example, the bloom value of the gelatin is 10 bloom, 20 bloom, 30 bloom, 50 bloom, 70 bloom, 80 bloom, 100 bloom, 125 bloom, 150 bloom, 180 bloom, 200 bloom, 225 bloom, 240 bloom, 260 bloom or 300 bloom.

Optionally, the gelatin has a concentration of 5-200 ppm in the electrolytic solution. For example, the concentration of the gelatin in the electrolytic solution is 5 ppm, 10 ppm, 20 ppm, 30 ppm, 40 ppm, 50 ppm, 60 ppm, 70 ppm, 80 ppm, 100 ppm, 120 ppm, 150 ppm, 180 ppm or 200 ppm.

On the electrochemical aspect, the auxiliary agent regulates desorption equilibrium of the inhibitor on the copper surface and thus accelerates the deposition of copper ions, and on the aspect of organization regulation, the auxiliary agent controls the concentration of electrocrystallization defects and induces generation of annealing twins in the subsequent thermal treatment step. Electroplated annealed twinned copper material can only be obtained when both the inhibitor and the auxiliary agent are present.

Optionally, the polystyrene sulfonate and the polyethylene sulfonate independently have a molecular mass of 1000-100000. optionally, the polystyrene sulfonate and the polyethylene sulfonate independently have a molecular mass of 2000-50000. For example, the molecular mass of the polystyrene sulfonate or the polyethylene sulfonate is independently 1000, 2000, 3000, 5000, 8000, 10000, 12500, 15000, 17000, 20000, 25000, 35000, 40000, 50000, 60000, 70000, 80000 or 100000. The auxiliary agent achieves its best effectiveness within such molecular mass range.

Optionally, the alkyl sulfonate and the alkylbenzene sulfonate both have more than or equal to 12 carbon atoms but less than or equal to 24. The auxiliary agent achieves its best effectiveness within such alkyl chain range.

Optionally, the auxiliary agent has a concentration of 10-500 ppm in the electrolytic solution. Optionally, the concentration of the auxiliary agent in the electrolytic solution is 10 ppm, 20 ppm, 30 ppm, 40 ppm, 50 ppm, 60 ppm, 70 ppm, 80 ppm, 100 ppm, 150 ppm, 200 ppm, 230 ppm, 260 ppm, 300 ppm, 350 ppm, 400 ppm or 500 ppm.

Optionally, the electrolytic solution further comprises copper ions, sulfuric acid, chlorine ions and water.

Optionally, the copper ions have a concentration of 20-70 g/L in the electrolytic solution. For example, the concentration of copper ions in the electrolytic solution is 20 g/L, 30 g/L, 40 g/L, 50 g/L, 60 g/L or 70 g/L.

In the preparation practice, the copper ions may come from a copper salt, for example, copper sulfate pentahydrate (CuSO₄·5H₂O). The copper ions may also come from pure copper ingots, pure copper powder or copper oxide powder.

Optionally, the sulfuric acid has a concentration of 20-200 g/L in the electrolytic solution. For example, the concentration of sulfuric acid in the electrolytic solution is 20 g/L, 25 g/L, 30 g/L, 35 g/L, 40 g/L, 50 g/L, 60 g/L, 70 g/L, 80 g/L, 100 g/L, 120 g/L, 150 g/L, 160 g/L, 180 g/L or 200 g/L.

In the preparation practice, the sulfuric acid may come from concentrated sulfuric acid; for example, it may be obtained by diluting 96-98 wt % concentrated sulfuric acid (H₂SO₄).

Furthermore, the chlorine ions have a concentration of 20-80 ppm in the electrolytic solution. For example, the concentration of chlorine ions in the electrolytic solution is 20 ppm, 30 ppm, 40 ppm, 45 ppm, 50 ppm, 60 ppm, 70 ppm or 80 ppm.

In the preparation practice, the chlorine ions may come from hydrochloric acid.

One object of the present application is to provide a preparation method for an electrolytic copper foil. The electrolytic copper foil is obtained by subjecting a pre-electroplated copper material to thermal treatment; the thermal treatment is performed at a temperature of more than or equal to 200° C.; the pre-electroplated copper material has a tensile strength of co and an elongation of 80, the electrolytic copper foil has a tensile strength of σ₁ and an elongation of δ₁, and σ₁>σ₀, and δ₁>δ₀; an electroplating method for the pre-electroplated copper material comprises the following steps:
(1) preparation of electrolytic solution
using the electrolytic solution for a copper foil as described above as the electrolytic solution;
(2) DC electroplating
immersing an anode and a cathode which serves as a conductive substrate into the electrolytic solution, and performing electroplating to obtain the pre-electroplated copper material.

The pre-electroplated copper material prepared by the method of the present application is subjected to thermal treatment. The copper foil forms a high proportion of annealing twins with increasing temperature during the thermal treatment (e.g., annealing), exhibits the unique properties of annealing strengthening and toughening in mechanics, and satisfies the demand for high-temperature mechanical properties of copper foils and the device reliability in circuit boards, secondary batteries, electromagnetic shielding, and other related applications; meanwhile, the method of the present application has the advantages of facile operation, low cost, strong practicality, and bright prospect of industrialization.

Optionally, a method for the preparation of electrolytic solution of step (1) comprises: dissolving a copper salt, sulfuric acid, a chloride compound, the inhibitor and the auxiliary agent with water, and dispersing to obtain the electrolytic solution.

In the present application, the anode in step (2) may be selected from a soluble anode such as a phosphorus copper anode or an insoluble anode such as a pure titanium anode or a metal oxide coated titanium anode.

Optionally, the phosphorus copper anode has a phosphorus content of 0.03-0.075 wt %. For example, the phosphorus content of the phosphorus copper anode is 0.03 wt %, 0.04 wt %, 0.05 wt %, 0.06 wt % or 0.07 wt %.

Optionally, the metal oxide coated titanium anode may be a titanium anode coated with a metal oxide mixture of iridium and tantalum.

Optionally, the anode is subjected to electrolytic activation treatment. The conditions of the electrolytic activation treatment are not particularly limited in the present application; the electrolytic activation treatment may be performing electrolysis for 30 min at a constant current of 1 A/dm² in a electrolytic solution only containing copper ions, sulfuric acid, and chlorine ions, or employ other electrolytic activation parameters commonly used in the field, provided that the surface of the material forms a uniform black phosphide film.

Optionally, in step (2), the electroplating is performed at a temperature of 20-50° C. For example, the temperature of electroplating is 20° C., 23° C., 25° C., 28° C., 30° C., 35° C., 40° C., 45° C. or 50° C.

Optionally, in step (2), the electroplating is performed at a constant temperature.

Optionally, in step (2), the electroplating is performed at a current density of 0.5-25 A/dm², such as 0.5 A/dm², 1 A/dm², 1.5 A/dm², 2 A/dm², 3 A/dm², 4 A/dm², 5 A/dm², 6 A/dm², 7 A/dm², 8 A/dm², 8.5 A/dm², 9 A/dm², 10 A/dm², 11 A/dm², 12 A/dm², 15 A/dm², 18 A/dm², 20 A/dm², 23 A/dm² or 25 A/dm².

Optionally, in step (2), the electroplating is performed for a period of 20-1800 min. For example, the period of the electroplating is 20 min, 30 min, 40 min, 60 min, 80 min, 90 min, 120 min, 150 min, 180 min, 200 min, 240 min, 280 min, 300 min, 350 min, 450 min, 500 min, 550 min, 600 min, 700 min, 800 min, 850 min, 900 min, 1000 min, 1100 min, 1200 min, 1250 min, 1300 min, 1400 min, 1500 min, 1600 min, 1700 min or 1750 min.

Optionally, the electroplating in step (2) is accompanied with agitation to the electrolytic solution.

Optionally, the agitation comprises at least one of circulating jet stream, air agitation, magnetic agitation and mechanical agitation.

However, the agitation is not limited to the above listed methods, and other commonly used agitation methods in the field are also applicable to the present application.

Optionally, the thermal treatment comprises annealing treatment.

Optionally, the thermal treatment comprises: heating the pre-electroplated copper material in an inert protective atmosphere to a temperature for the thermal treatment, and holding the temperature.

Optionally, the thermal treatment is performed at a temperature of 200-400° C. For example, the temperature of the thermal treatment is 200° C., 225° C., 260° C., 280° C., 300° C., 320° C., 350° C., 370° C. or 400° C.

Optionally, the temperature is held for a period of 20-1200 min. Optionally, the temperature is held for a period of 30-120 min. For example, the temperature holding period is 20 min, 30 min, 40 min, 60 min, 80 min, 90 min, 120 min, 150 min, 180 min, 200 min, 240 min, 280 min, 300 min, 350 min, 450 min, 500 min, 550 min, 600 min, 700 min, 800 min, 850 min, 900 min, 1000 min, 1100 min or 1200 min.

The type of the conductive substrate is not particularly limited in the present application; for example, the conductive substrate may be selected from copper, titanium, tantalum, gold, tungsten, cobalt, nickel, and alloy prepared from at least two of the above, or materials prepared from the alloy such as boards, thin films, printed circuit boards, and wafer seed layers.

The preparation method for the conductive substrate is not limited in the present application, which may be selected from, for example, electroplating, chemical plating, sputtering, fusion casting and other preparation methods.

In the present application, the conductive substrate may undergo pre-treatment before use; for example, a substrate with greasy dirt and oxides on the surface can be subjected to degreasing, acid washing and water washing thoroughly before use to completely remove the greasy dirt and oxides on the surface, thereby exposing a fresh and clean substrate surface.

The degreasing may be soaking and stirring in a 10 wt % sodium hydroxide (NaOH) solution or other degreasing methods commonly used in the field.

The acid washing may be soaking and stirring in a 5 wt % sulfuric acid (H₂SO₄) solution or other oxide removal methods commonly used in the field.

The method of the present application further comprises a step of separating the copper foil formed by electroplating from the conductive substrate.

Furthermore, the copper foil is obtained by subjecting a pre-electroplated copper material to thermal treatment; the thermal treatment is performed at a temperature of more than or equal to 200° C.; in a tensile test, the pre-electroplated copper material has a tensile strength of 00 and an elongation of 80, the electrolytic copper foil has a tensile strength of σ₁ and an elongation of 8, and σ₁>σ₀, and δ₁>δ₀; an electroplating method for the pre-electroplated copper material comprises the following steps:
(1) preparation of electrolytic solution
dissolving a copper salt, sulfuric acid, a chloride compound, the inhibitor and the auxiliary agent with water, and dispersing thoroughly and uniformly to obtain the electrolytic solution; the electrolytic solution contains 20-70 g/L of copper ions, 20-200 g/L of sulfuric acid, 20-80 ppm of chlorine ions, 5-200 ppm of the inhibitor, 10-500 ppm of the auxiliary agent and a remainder of water, the inhibitor comprises gelatin, and the auxiliary agent is selected from at least one of polystyrene sulfonate, polyethylene sulfonate, alkyl sulfonate and alkylbenzene sulfonate;
wherein the alkyl sulfonate and the alkylbenzene sulfonate both have more than or equal to 12 carbon atoms;
(2) DC electroplating
immersing an anode and a cathode which serves as a conductive substrate into the electrolytic solution, and performing electroplating at 20-50° C. for 20-1800 min with a constant current at a current density of 0.5-25 A/dm².

One object of the present application is to provide an electrolytic copper foil, and the electrolytic copper foil is obtained by the preparation method for an electrolytic copper foil as described above.

The electrolytic copper foil of the present application has a high proportion of annealing twin boundaries, and the grains having annealing twin boundaries account for 50% or more of the total number of grains in the copper material or the volume of annealed twinned organization accounts for 50% or more of the total volume of the copper material. The copper foil exhibits strengthening and toughening mechanical properties with increasing annealing temperature.

The grains having annealing twin boundaries account for 50% or more of the total number of grains in the copper material, such as 50%, 55%, 60%, 65%, 70%, 75%, 80%, 85%, 90%, 95%, 97%, 98% or 99%. The volume of annealed twinned organization accounts for 50% or more of the total volume of the copper material, such as 50%, 55%, 60%, 65%, 70%, 75%, 80%, 85%, 90%, 95%, 97%, 98% or 99%.

The present application provides use of the electrolytic copper foil, and the electrolytic copper foil is used in printed circuit board base materials, secondary battery collectors or metallic electromagnetic shielding film.

Compared with the prior art, the present application has the following beneficial effects.

The present application provides the electrolytic solution for a copper foil comprising particular additives. Through simple chemical regulation such as selection and combination of additives for the electrolytic (electroplating) solution, the pre-electroplated copper material, obtained by electroplating with the electrolytic solution for a copper foil, is capable of forming a high proportion of annealing twin boundaries after thermal treatment at 200° C. or higher temperature, possessing unique “annealing-induced strengthening and toughening” mechanical properties. The proportion of annealing twins increases with the increase of temperature, which greatly inhibits the recrystallization rate. The copper foil exhibits excellent mechanical properties. There is no significant grain growth under thermal treatment. The copper foil even has higher tensile strength than before the annealing, and at the same time its elongation increases by about a half. The copper foil of the present application has obvious advantages in mechanical properties, contrasting sharply with the commercially available electrolytic (electroplated) copper foils and growth twinned copper foils which show high temperature mechanical behavior of “annealing-induced softening and toughening”.

The electrolytic copper foil prepared by the method of the present application is subjected to thermal treatment. The electrolytic copper foil forms a high proportion of annealing twins with increasing temperature during the thermal treatment (e.g., annealing), exhibits the unique properties of annealing strengthening and toughening in mechanics, and satisfies the demand for high-temperature mechanical properties of copper foils and the device reliability in circuit boards, secondary batteries, electromagnetic shielding, and other related applications; meanwhile, the method of the present application has the advantages of facile operation, low cost, strong practicality, and bright prospect of industrialization.

### BRIEF DESCRIPTION OF DRAWINGS

FIG. 1 shows a cross-sectional focused ion beam micrograph of an electrolytic copper foil before annealed in Example 1;

FIG. 2 shows a cross-sectional focused ion beam micrograph of an electrolytic copper foil after annealed at 200° C. for 1 hour in Example 1;

FIG. 3 shows a cross-sectional focused ion beam micrograph of an electrolytic copper foil after annealed at 400° C. for 1 hour in Example 1;

FIG. 4 shows a cross-sectional focused ion beam micrograph of an electrolytic copper foil before annealed in Comparative Example 1.

### DETAILED DESCRIPTION

In order that the above objects, features and advantages of the present application can be more apparent and understandable, embodiments of the present application are described in detail hereinafter in conjunction with the accompanying drawings, but are not to be construed as limiting the scope of the present application.

In the present application, the electrolytic copper foil belongs to a twinned copper material.

The twinned copper material shows (110) plane-preferred orientation. The twinned copper material comprises a twinned organization, the twinned organization comprises twin layers. The twin layers are mainly distributed along an angle of 45° to the grain growth direction; the grains having twin layers account for 50% or more of the total number of grains in the twinned copper material, and/or the volume of the twinned organization accounts for 50% or more of the total volume of the twinned copper material.

In the present application, the “mainly” in the sentence of “the twin layers are mainly distributed along an angle of 45° to the grain growth direction” refers to more than or equal to 50% (e.g., 52%, 55%, 60%, 65%, 70%, 75%, 80%, 85%, 90%, 92%, 95%, 96%, 98%, 99% or 100%) of the twin layers. The “angle” refers to an acute angle between the twin layers and the grain growth direction.

In the present application, the proportion of grains having twin layers in the total number of grains in the twinned copper material may be 50%, 55%, 60%, 65%, 70%, 75%, 80%, 85%, 90%, 95%, 97%, 98% or 99%.

In the present application, the ratio of the volume of the twinned organization to the total volume of the twinned copper material may be 50%, 52%, 55%, 60%, 63%, 65%, 70%, 75%, 80%, 85%, 88%, 90%, 95%, 97%, 98% or 99%.

The twinned copper material provided by the present application is (110)-preferred oriented annealed twinned copper, in which a high proportion of twin boundaries are present stably, and compared with highly (110)-preferred oriented electroplated nanotwinned copper, has superior thermal organization stability, has no abnormal grain growth over the common temperature range of thermal treatment (e.g., 200° C.-400° C.) for electronic materials, and exhibits a unique property that the ratio of twin layers does not decrease but increases.

The twinned copper material of the present application can be applied to the copper plating related field represented by the manufacturing and packaging of integrated circuits and circuit boards; the stability of thermal-treated organization of electroplating copper material is optimized, i.e., the thermal treatment is introduced to generate and stabilize the twinned organization, inhibiting the abnormal growth of grains and the degeneration of material strength in this process.

Optionally, the twinned copper material is analyzed by XRD diffraction and the intensity ratio of the (220)/(111) diffraction peaks is greater than 2, such as 3, 4, 5, 6, 7, 8, 9 or 10. Higher intensity ratios means that more grains grow orientationally along the (110) plane and the 45° growth orientation of grains relative to twin layers are higher.

Furthermore, the twinned copper material is obtained by subjecting a pre-electroplated copper material having (111) plane-preferred orientation to thermal treatment, and the thermal treatment is performed at a temperature of more than or equal to 200° C. For example, the temperature of the thermal treatment may be 200° C., 220° C., 240° C., 260° C., 300° C., 350° C., 400° C. or 450° C.

In the present application, the pre-electroplated copper material refers to an electroplating copper material without annealing treatment.

By subjecting the pre-electroplated copper material to thermal treatment, the (111) plane-preferred orientation can be converted to (110) plane-preferred orientation, accompanied with the formation of a high proportion of annealing twins. The twin layers are mainly distributed along an angle of 45° to the grain growth direction. The resulted twinned copper material exhibits excellent thermal stability.

In an optional embodiment, the thermal treatment is carried out in a manner of annealing.

A preparation method for the twinned copper material comprises the following steps.
(1) Preparation of electrolytic solution
the electrolytic solution contains copper ions, sulfuric acid, chlorine ions, additives and water, the additives comprise an inhibitor and an auxiliary agent, and the auxiliary agent is selected from at least one of organic sulfonate.
(2) DC electroplating
immersing an anode and a cathode which serves as a conductive substrate into the electrolytic solution, and performing electroplating to obtain the pre-electroplated copper material.
(3) The pre-electroplated copper material is subjected to thermal treatment, and the thermal treatment is performed at a temperature of more than or equal to 200° C. to obtain the twinned copper material.

In the method of the present application, the combination of additives for pre-electroplated has an important effect on the structure of the pre-electroplated material: the inhibitor added to the electrolytic solution can reduce the deposition rate to avoid bulky and non-compact crystallization; the auxiliary agent added to the electrolytic solution can increase the deposition rate. The competitive effectiveness between the auxiliary agent and the inhibitor contributes to the dynamic and controllable desorption of the double layer inhibitor, and introduces the defect concentration of electric crystallization which is necessary for the generation of annealing twin boundaries.

In the method of the present application, annealing twin boundaries are used to replace growth twins directly obtained by conventional electroplating, which can ensure the stable existence of a high proportion of twin boundaries during the thermal treatment process, opening up a new field for the preparation and application of highly (110)-preferred oriented twinned copper material.

On the basis of the twinned material, the present application provides an electrolytic solution for a copper foil and an electrolytic copper foil.

The electrolytic solution for a copper foil comprises an additive, the additive comprises an inhibitor and an auxiliary agent, and the auxiliary agent comprises at least one of polystyrene sulfonate, polyethylene sulfonate, alkyl sulfonate and alkylbenzene sulfonate;

wherein the alkyl sulfonate and the alkylbenzene sulfonate both have more than or equal to 12 carbon atoms.

A preparation method for the electrolytic copper foil comprises: subjecting a pre-electroplated copper material to thermal treatment; the thermal treatment is performed at a temperature of more than or equal to 200° C.; the pre-electroplated copper material has a tensile strength of σ₀ and an elongation of 80, the electrolytic copper foil has a tensile strength of σ₁ and an elongation of δ₁, and σ₁>σ₀, and δ₁>δ₀; an electroplating method for the pre-electroplated copper material comprises the following steps:
(1) preparation of electrolytic solution
using the electrolytic solution for a copper foil as described above as the electrolytic solution;
(2) DC electroplating
immersing an anode and a cathode which serves as a conductive substrate into the electrolytic solution, and performing electroplating to obtain the pre-electroplated copper material.

The technical solutions of the present application is further described below with reference to the accompanying drawings through embodiments.

### Example 1

This example provides an electrolytic solution for a copper foil, comprising:
30 g/L of copper ions, 30 g/L of sulfuric acid, 30 ppm of chlorine ions, 50 ppm of an inhibitor, 300 ppm of an auxiliary agent, and 250 mL of pure water;
wherein the inhibitor is gelatin with a coagulation value of 100 bloom, and the auxiliary agent is sodium polystyrene sulfonate with a molecular mass of 40000.

This example provides a method for preparing an electrolytic copper foil using the above electrolytic solution for a copper foil, the method comprising:

### (1) DC Electroplating

a. Cathode pre-treatment. A high-purity titanium plate to be used as the cathode was sequentially subjected to alkaline washing, acid washing and water washing.
b. DC electroplating. The titanium cathode and a phosphorus copper anode (phosphorus content of 0.05 wt %) were immersed into the above electrolytic solution for a copper foil, and applied with 300 rpm mechanical agitation; the electrolytic solution was controlled at a constant temperature of 25° C. Then a rectifier was connected into the system, and electroplating was performed for 120 min with a current density of 3 A/dm² to obtain a pre-electroplated copper material.
c. Post-treatment of copper foil. The pre-electroplated copper material was removed from the electrolytic solution and separated from the substrate, the plating layer was rinsed repeatedly with pure water to remove the residual electrolytic solution, and finally the surface of the copper foil was blown to dry with compressed air.

### (2) Annealing Treatment.

The pre-electroplated copper material was placed in a tube furnace; with introduction of a nitrogen protective atmosphere, the furnace was arranged to heat to 200° C. from room temperature at 10° C./min and hold for 1 hour and then cool naturally; the electrolytic copper foil was taken out.

### Example 2

The difference between this example and Example 1 is that the temperature of the annealing treatment in step (2) was 250° C.

### Example 3

The difference between this example and Example 1 is that the temperature of the annealing treatment in step (2) was 300° C.

### Example 4

The difference between this example and Example 1 is that the temperature of the annealing treatment in step (2) was 350° C.

### Example 5

The difference between this example and Example 1 is that the temperature of the annealing treatment in step (2) was 400° C.

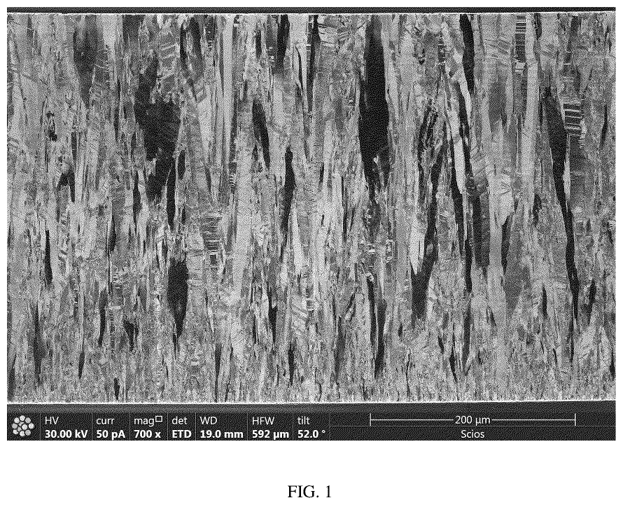

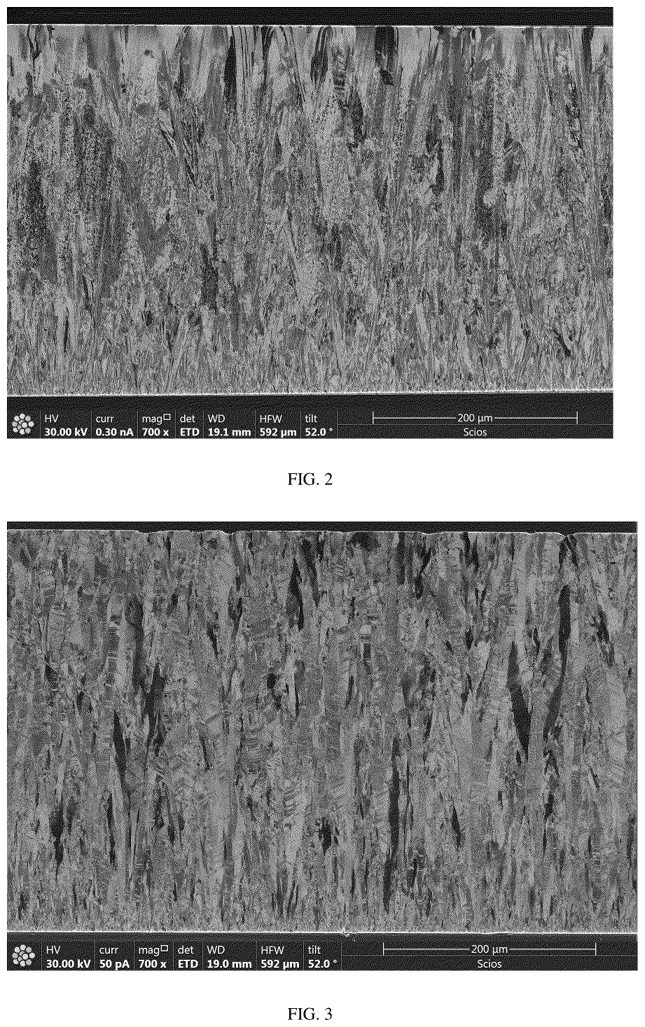

The cross-sectional focused ion beam micrographs of the pre-electroplated copper material before annealed in Example 1, the annealed electrolytic copper foil (temperature: 200° C., period: 1 hour) in Example 1, and the annealed electrolytic copper foil (temperature: 400° C., period: 1 hour) in Example 5 are shown in FIGS. 1, 2 and 3, respectively. As can be seen from FIG. 1, the electrolytic copper foil has a thickness of 350 μm and is mainly composed of columnar grains parallel to the growth direction. As can be seen from FIG. 2 and FIG. 3, annealing twin boundaries are observed after annealing at 200° C., and the grains having twin boundaries account for more than 70% of the total number of grains in the electrolytic copper foil.

According to GB/T 5230-2020 standard, the pre-electroplated copper material before annealed in Example 1 and the annealed electrolytic copper foils in Examples 1-5 are cut and sampled; tensile test is performed, and the results are shown in Table 1.

TABLE 1

| | | Annealing | | Tensile | |
|---|---|---|---|---|---|
| | Anneal- | Tem- | Holding | Strength | Elongation |
| | ing | perature | period | (MPa) | (%) |
| Example 1 | No | Room | — | 259.23 ± 17.67 | 15.61 ± 2.63 |
| | | temperature | | | |
| Example 1 | Yes | 200° C. | 1 hour | 290.08 ± 4.59 | 23.14 ± 2.66 |
| Example 2 | Yes | 250° C. | 1 hour | 281.10 ± 7.19 | 26.40 ± 1.84 |
| Example 3 | Yes | 300° C. | 1 hour | 287.37 ± 3.57 | 27.50 ± 3.70 |
| Example 4 | Yes | 350° C. | 1 hour | 303.93 ± 8.60 | 30.89 ± 2.14 |
| Example 5 | Yes | 400° C. | 1 hour | 296.84 ± 3.07 | 32.00 ± 1.02 |

Note:
The tensile strength and elongation are the average value of 5 repeated tensile tests.

As can be seen from Table 1, with the annealing temperature increases, the tensile strength of electrolytic copper foil increases to different degrees, and the elongation increases to different degrees, without thermal treatment, the tensile strength is more than or equal to 250 MPa, and the elongation is more than or equal to 15%; after one hour of 200° C. annealing, the tensile strength is more than or equal to 280 MPa, and the elongation is more than or equal to 23%; after one hour of annealing at 200-400° C., the tensile strength is within 280-310 MPa, increasing as the annealing temperature increases, and the elongation is within 23-32%, increasing as the annealing temperature increases.

Taking one hour of 400° C. annealing as an example, after annealing, the tensile strength increases from 259.2 MPa to 296.8 MPa, and the elongation increases from 15.6% to 32.0%.

### Comparative Example 1-1

This comparative example provides a nanotwinned copper foil and a preparation method thereof, and the method comprises the following steps.

### (1) Preparation of Electrolytic Solution

The electrolytic solution was prepared with the following components and proportions and dispersed uniformly: 30 g/L of copper ions, 30 g/L of sulfuric acid, 30 ppm of chlorine ions, 50 ppm of an inhibitor, no auxiliary agent, and 250 mL of pure water; wherein the inhibitor was gelatin with a coagulation value of 100 bloom.

### (2) DC Electroplating

a. Cathode pre-treatment. A high-purity titanium plate to be used as the cathode was sequentially subjected to alkaline washing, acid washing and water washing.
b. DC electroplating. The titanium cathode and a phosphorus copper anode (phosphorus content of 0.05 wt %) were immersed into the electrolytic solution, and applied with 300 rpm mechanical agitation; the electrolytic solution was controlled at a constant temperature of 25° C. Then a rectifier was connected into the system, and electroplating was performed for 120 min with a current density of 3 A/dm².
c. Post-treatment of copper foil. The copper foil was removed from the electrolytic solution and separated from the substrate, the plating layer was rinsed repeatedly with pure water to remove the residual electrolytic solution, and finally the surface of the copper foil was blown to dry with compressed air.

### (3) Annealing Treatment.

The electrolytic copper foil was placed in a tube furnace; with introduction of a nitrogen protective atmosphere, the furnace was arranged to heat to 200° C. from room temperature at 10° C./min and hold for 1 hour and then cool naturally; the copper foil was taken out.

### Comparative Example 1-2

The difference between this comparative example and Comparative Example 1-1 is that the temperature of the annealing in step (3) was 250° C.

### Comparative Example 1-3

The difference between this comparative example and Comparative Example 1-1 is that the temperature of the annealing in step (3) was 300° C.

### Comparative Example 1-4

The difference between this comparative example and Comparative Example 1-1 is that the temperature of the annealing in step (3) was 350° C.

### Comparative Example 1-5

The difference between this comparative example and Comparative Example 1-1 is that the temperature of the annealing in step (3) was 400° C.

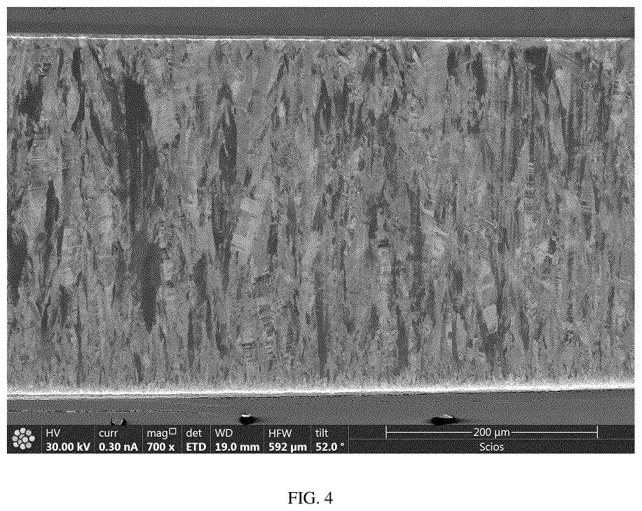

The cross-sectional focused ion beam micrograph of the electrolytic copper foil before annealed in Comparative Example 1 is shown in FIG. 4, 170 μm, mainly showing columnar grains parallel to the growth direction; growth twin boundaries can be observed before the annealing.

According to GB/T 5230-2020 standard, the electrolytic copper foil before annealed in Comparative Example 1 and the annealed electrolytic copper foils in Comparative Examples 1-1 to 1-5 are cut and sampled; tensile test is performed, and the results are shown in Table 2.

TABLE 2

| | | Annealing | | Tensile | |
|---|---|---|---|---|---|
| | Anneal- | Tem- | Holding | Strength | Elongation |
| | ing | perature | period | (MPa) | (%) |
| Comparative | No | Room | — | 407.68 ± 27.92 | 6.54 ± 2.77 |
| Example 1-1 | | tem- | | | |
| | | perature | | | |
| Comparative | Yes | 200° C. | 1 hour | 429.04 ± 41.34 | 5.98 ± 3.06 |
| Example 1-1 | | | | | |
| Comparative | Yes | 250° C. | 1 hour | 440.33 ± 40.1 | 4.39 ± 4.46 |
| Example 1-2 | | | | | |
| Comparative | Yes | 300° C. | 1 hour | 417.66 ± 34.41 | 6.49 ± 3.92 |
| Example 1-3 | | | | | |
| Comparative | Yes | 350° C. | 1 hour | 402.8 ± 38.77 | 6.81 ± 3.51 |
| Example 1-4 | | | | | |
| Comparative | Yes | 400° C. | 1 hour | 421.71 ± 45.50 | 6.14 ± 4.93 |
| Example 1-5 | | | | | |

Note:
The tensile strength and elongation are the average value of 5 repeated tensile tests.

As can be seen from Table 2, comparing the electrolytic copper foil annealed at 400° C. with the one before annealed, the tensile strength increases from 407.7 MPa to 421.7 MPa, and the elongation decreases from 6.5% to 6.1%.

In terms of the mechanical properties of the examples and Comparative Examples 1-1 to 1-5 of the present application, compared with the growth twinned organization, the annealed twinned organization having twin boundaries orientationally distributed has an overall decrease of about 20% in the tensile strength, but its elongation is increased substantially to 5 times of the original, which alleviates the brittleness problem of the growth twinned organization.

### Comparative Example 2-1

This comparative example provides a commercial electrolytic copper foil and a preparation method thereof, and the method comprises the following steps.

### (1) Preparation of Electrolytic Solution

The electrolytic solution was prepared with the following components and proportions and dispersed uniformly: 40 g/L of copper ions, 140 g/L of sulfuric acid, 50 ppm of chlorine ions, additives (from Shanghai Sinyang Co., Ltd., 12 mL/L of inhibitor SYS3210L 210L, 8 mL/L of accelerator SYS3210A), and 250 mL of pure water.

### (2) DC Electroplating

a. Cathode pre-treatment. A high-purity titanium plate to be used as the cathode was sequentially subjected to alkaline washing, acid washing and water washing.
b. DC electroplating. The titanium cathode and a phosphorus copper anode (phosphorus content of 0.05 wt %) were immersed into the electrolytic solution, and applied with 300 rpm mechanical agitation; the electrolytic solution was controlled at a constant temperature of 25° C. Then a rectifier was connected into the system, and electroplating was performed for 120 min with a current density of 3 A/dm².
c. Post-treatment of copper foil. The electrolytic copper foil was removed from the electrolytic solution and separated from the substrate, the plating layer was rinsed repeatedly with pure water to remove the residual electrolytic solution, and finally the surface of the copper foil was blown to dry with compressed air.

### (3) Annealing Treatment.

The electrolytic copper foil was placed in a tube furnace; the furnace was arranged to heat to 200° C. from room temperature at 10° C./min and hold for 1 hour and then cool naturally; the electrolytic copper foil was taken out.

### Comparative Example 2-2

The difference between this comparative example and Comparative Example 2-1 is that the temperature of the annealing in step (3) was 250° C.

### Comparative Example 2-3

The difference between this comparative example and Comparative Example 2-1 is that the temperature of the annealing in step (3) was 300° C.

### Comparative Example 2-4

The difference between this comparative example and Comparative Example 2-1 is that the temperature of the annealing in step (3) was 350° C.

### Comparative Example 2-5

The difference between this comparative example and Comparative Example 2-1 is that the temperature of the annealing in step (3) was 400° C.

According to GB/T 5230-2020 standard, the electrolytic copper foil before annealed in Comparative Example 2-1 and the annealed electrolytic copper foils in Comparative Examples 2-1 to 2-5 are cut and sampled; tensile test is performed, and the results are shown in Table 3.

TABLE 3

| | | Annealing | | Tensile | |
|---|---|---|---|---|---|
| | Anneal- | Tem- | Holding | Strength | Elongation |
| | ing | perature | period | (MPa) | (%) |
| Comparative | No | Room | — | 322.45 ± 6.42 | 20.73 ± 0.45 |
| Example 2-1 | | tem- | | | |
| | | perature | | | |
| Comparative | Yes | 200° C. | 1 hour | 289.51 ± 6.40 | 24.47 ± 2.36 |
| Example 2-1 | | | | | |
| Comparative | Yes | 250° C. | 1 hour | 286.51 ± 17.03 | 25.1 ± 2.44 |
| Example 2-2 | | | | | |
| Comparative | Yes | 300° C. | 1 hour | 227.29 ± 2.70 | 32.13 ± 1.64 |
| Example 2-3 | | | | | |
| Comparative | Yes | 350° C. | 1 hour | 210.38 ± 2.45 | 31.10 ± 1.53 |
| Example 2-4 | | | | | |
| Comparative | Yes | 400° C. | 1 hour | 200.72 ± 1.24 | 29.51 ± 1.27 |
| Example 2-5 | | | | | |

Note:
The tensile strength and elongation are the average value of 5 repeated tensile tests.

As can be seen from Table 3, comparing the electrolytic copper foil annealed at 400° C. with the one before annealed, the tensile strength decreases from 322.5 MPa to 200.7 MPa, and the elongation increases from 20.7% to 29.5%.

In terms of the mechanical properties of the examples and comparative examples of the present application, the special annealed twinned organization has comparable elongation to the common nanocrystalline organization; however, as the temperature of thermal treatment increases, the tensile strength of the common nanocrystalline organization continues to decrease, while the tensile strength of the annealed twinned organization continues to increase, and at the highest condition of 400° C. the latter (the electrolytic copper foil having annealing twins of the present application) is larger than the former (the electrolytic copper foil having common microcrystalline organization) by 30%. The electrolytic copper foil having annealing twins of the present application exhibits excellent high-temperature mechanical properties of annealing strengthening and toughening.

### Comparative Example 3

The copper foil provided in Comparative Example 3 was prepared in accordance with a method disclosed in the literature (Reference: Li, Y. J., Tu, K. N., & Chen, C. (2020). Tensile properties and thermal stability of unidirectionally <111>-oriented nanotwinned and <110>-oriented microtwinned copper. Materials, 13 (5), 1211).

In this comparative example, nano- and micro-twinned copper foils with high and low twin boundary density were prepared, and the mechanical properties changing with annealing temperature increase or period lengthening are shown in Table 4.

TABLE 4

| | | Annealing | | Tensile | |
|---|---|---|---|---|---|
| | Anneal- | Tem- | Holding | Strength | Elongation |
| Twin Density | ing | perature | period | (MPa) | (%) |
| Micro-twinned | No | Room | — | 412 | 6 |
| copper | | temperature | | | |
| foil with low twin | Yes | 250° C. | 10 min | 131 | 15 |
| boundary density | Yes | 250° C. | 180 min | 107 | 15 |
| Nano-twinned | Yes | Room | — | 748 | 6 |
| copper | | temperature | | | |
| foil with high twin | Yes | 250° C. | 10 min | 700 | 9 |
| boundary density | Yes | 250° C. | 180 min | 670 | 12 |

As can be seen from Table 4, for the two kinds of copper foils provided in Comparative Example 3 after the annealing, the micro-twinned copper foil with low twin boundary density fails to produce annealed twinned organization, and therefore the strength is rapidly reduced to 25% of the original in the thermal treatment process; the nano-twinned copper foil with high twin boundary density also continues to decrease despite the high initial tensile strength; those two both show different degrees of decreasing tendency, which are in stark contrast to the present application; the elongations of the two both increase with the annealing temperature and period, but the increase is limited, which is about half of that of the present application under similar conditions. Overall, the tensile strength and elongation of the present application are better.

In summary, in the present application, through simple chemical regulation such as selection and combination of additives for the electrolytic (electroplating) solution, the pre-electroplated copper material, obtained by electroplating with the electrolytic solution, is capable of forming a high proportion of annealing twin boundaries after thermal treatment at 200° C. or higher temperature, possessing unique “annealing-induced strengthening and toughening” mechanical properties. The proportion of annealing twins increases with the increase of temperature, which greatly inhibits the recrystallization rate. The electrolytic copper foil exhibits excellent mechanical properties. There is no significant grain growth under the experimental conditions of thermal treatment. The electrolytic copper foil even has higher tensile strength than before the annealing, and at the same time its elongation increases by about a half. The copper foil of the present application has obvious advantages in mechanical properties, contrasting sharply with the commercially available electrolytic (electroplated) copper foils and growth twinned copper foils which show high temperature mechanical behavior of “annealing-induced softening and toughening”.

The applicant has stated that although the detailed method of the present application is described through the above embodiments, the present application is not limited to the above detailed method, which means that the implementation of the present application does not necessarily depend on the above detailed method. It should be apparent to those skilled in the art that any improvements made to the present application, equivalent substitutions of various raw materials of the product, the addition of adjuvant ingredients, the selection of specific manners, etc., all fall within the protection scope and the disclosure scope of the present application.

1. An electrolytic solution for a copper foil, comprising an additive, wherein the additive comprises an inhibitor and an auxiliary agent, and the auxiliary agent comprises at least one of polystyrene sulfonate, polyethylene sulfonate, alkyl sulfonate and alkylbenzene sulfonate; wherein the alkyl sulfonate and the alkylbenzene sulfonate both have more than or equal to 12 carbon atoms.

2. The electrolytic solution for a copper foil according to claim 1, wherein the inhibitor comprises gelatin;
the gelatin has a coagulation value of 10-300 bloom;
the gelatin has a concentration of 5-200 ppm in the electrolytic solution.

3. The electrolytic solution for a copper foil according to claim 1, wherein the polystyrene sulfonate and the polyethylene sulfonate independently have a molecular mass of 1000-100000, preferably 2000-50000;
the alkyl sulfonate and the alkylbenzene sulfonate both have more than or equal to 12 carbon atoms but less than or equal to 24;
the auxiliary agent has a concentration of 10-500 ppm in the electrolytic solution.

4. The electrolytic solution for a copper foil according to claim 1, wherein the electrolytic solution further comprises copper ions, sulfuric acid, chlorine ions and water, and the copper ions have a concentration of 20-70 g/L in the electrolytic solution; the sulfuric acid has a concentration of 20-200 g/L in the electrolytic solution; the chlorine ions have a concentration of 20-80 ppm in the electrolytic solution.

5. The electrolytic solution for a copper foil according to claim 3, wherein the electrolytic solution further comprises copper ions, sulfuric acid, chlorine ions and water, and the copper ions have a concentration of 20-70 g/L in the electrolytic solution; the sulfuric acid has a concentration of 20-200 g/L in the electrolytic solution; the chlorine ions have a concentration of 20-80 ppm in the electrolytic solution.

6. A preparation method for an electrolytic copper foil, wherein the electrolytic copper foil is obtained by subjecting a pre-electroplated copper material to thermal treatment; the thermal treatment is performed at a temperature of more than or equal to 200° C.; in a tensile test, the pre-electroplated copper material has a tensile strength of σ₀ and an elongation of δ₀, the electrolytic copper foil has a tensile strength of σ₁ and an elongation of δ₁, and σ₁>σ₀, and δ₁>δ₀; an electroplating method for the pre-electroplated copper material comprises the following steps:
(1) preparation of electrolytic solution using the electrolytic solution according to claim 4 as the electrolytic solution;
(2) DC electroplating immersing an anode and a cathode which serves as a conductive substrate into the electrolytic solution, and performing electroplating to obtain the pre-electroplated copper material.

7. A preparation method for an electrolytic copper foil, wherein the electrolytic copper foil is obtained by subjecting a pre-electroplated copper material to thermal treatment; the thermal treatment is performed at a temperature of more than or equal to 200° C.; in a tensile test, the pre-electroplated copper material has a tensile strength of σ₀ and an elongation of δ₀, the electrolytic copper foil has a tensile strength of on and an elongation of δ₁, and σ₁>σ₀, and δ₁>δ₀; an electroplating method for the pre-electroplated copper material comprises the following steps:
(1) preparation of electrolytic solution using the electrolytic solution according to claim 5 as the electrolytic solution; and
(2) DC electroplating immersing an anode and a cathode which serves as a conductive substrate into the plating solution, and performing electroplating to obtain the pre-electroplated copper material.

8. The preparation method for an electrolytic copper foil according to claim 6, wherein a method for the preparation of electrolytic solution of step (1) comprises:
dissolving a copper salt, sulfuric acid, a chloride compound, the inhibitor and the auxiliary agent with water, and dispersing to obtain the electrolytic solution;
in step (2), the electroplating is performed at a temperature of 20-50° C.;
in step (2), the electroplating is performed at a constant temperature;
in step (2), the electroplating is performed at a current density of 0.5-25 A/dm²;
in step (2), the electroplating is performed for a period of 20-1800 min;
the electroplating in step (2) is accompanied with agitation to the electrolytic solution, and the agitation comprises at least one of circulating jet stream, air agitation, magnetic agitation and mechanical agitation.

9. The preparation method for an electrolytic copper foil according to claim 6, wherein the thermal treatment comprises annealing treatment, comprising: heating the pre-electroplated copper material in an inert protective atmosphere to a temperature of 200-400° C. for the thermal treatment, and holding the temperature for 20-1200 min.

10. The preparation method for an electrolytic copper foil according to claim 9, wherein the electrolytic copper foil is obtained by subjecting a pre-electroplated copper material to thermal treatment; the thermal treatment is performed at a temperature of more than or equal to 200° C.; in a tensile test, the pre-electroplated copper material has a tensile strength of σ₀ and an elongation of 8, the electrolytic copper foil has a tensile strength of σ₁ and an elongation of δ₁, and σ₁>σ₀, and δ₁>δ₀; an electroplating method for the pre-electroplated copper material comprises the following steps:
(1) preparation of electrolytic solution dissolving a copper salt, sulfuric acid, a chloride compound, the inhibitor and the auxiliary agent with water, and dispersing thoroughly and uniformly to obtain the electrolytic solution; the electrolytic solution contains 20-70 g/L of copper ions, 20-200 g/L of sulfuric acid, 20-80 ppm of chlorine ions, 5-200 ppm of the inhibitor, 10-500 ppm of the auxiliary agent and a remainder of water, the inhibitor comprises gelatin, and the auxiliary agent is selected from at least one of polystyrene sulfonate, polyethylene sulfonate, alkyl sulfonate and alkylbenzene sulfonate;
wherein the alkyl sulfonate and the alkylbenzene sulfonate both have more than or equal to 12 carbon atoms; and
(2) DC electroplating immersing an anode and a cathode which serves as a conductive substrate into the electrolytic solution, and performing electroplating at 20-50° C. for 20-1800 min with a constant current at a current density of 0.5-25 A/dm².

11. An electrolytic copper foil, wherein the electrolytic copper foil is obtained by the preparation method for an electrolytic copper foil according to claim 6.

12. An electrolytic copper foil, wherein the electrolytic copper foil is obtained by the preparation method for an electrolytic copper foil according to claim 8.

13. An electrolytic copper foil, wherein the electrolytic copper foil is obtained by the preparation method for an electrolytic copper foil according to claim 9.

14. (canceled)

15. (canceled)

16. A printed circuit board base material, comprising the electrolytic copper foil according to claim 11.

17. A secondary battery collector, comprising the electrolytic copper foil according to claim 11.

18. A metallic electromagnetic shielding film, comprising the electrolytic copper foil according to claim 11.
